(19) United States
(12) Patent Application Publication
(10) Pub. No.: US 2008/0075292 A1
(43) Pub. Date: Mar. 27, 2008

(54) AUDIO PROCESSING APPARATUS SUITABLE FOR SINGING PRACTICE

(75) Inventors: Shih-Fang Wong, Taipei Hsien (TW); Chung-Jen Wang, Taipei Hsien (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/845,103

(22) Filed: Aug. 27, 2007

(30) Foreign Application Priority Data
Sep. 22, 2006 (CN) 200610062726.3

(51) Int. Cl. H03G 3/20; G10L 21/00

(52) U.S. Cl. 381/61; 434/307 A; 704/278

(57) ABSTRACT

An audio processing apparatus (20) connected between an audio source (10) and an audio output (30) is provided. The audio processing apparatus is suitable for singing practice of users and includes a vocal removing unit (210) and a pitch change unit (220). The vocal removing unit is for removing vocal signals from audio signals of the audio source, and the pitch change unit is for changing pitch of the audio signals and outputting the audio signals to the audio output.

### BACKGROUND

1. Technical Field

The present invention relates to audio processing apparatuses, and particularly to an audio processing apparatus suitable for singing practice.

2. Related Art

Most acoustic devices are generally equipped with features or functions that control the volume, bass, or treble, but not the pitch. If users sing karaoke with such an acoustic device and when a pitch of music goes beyond what the users' singing voices can reach, harmony between the music and the users' singing is destroyed and affects singing practices of the users. The term “Karaoke” refers to a form of entertainment that people sing popular songs into a microphone over pre-recorded backing tracks.

Further, if the vocals are not removed from the music, the users will also be affected.

Therefore, there is a need for providing an audio processing apparatus which can solve the problems listed above and are suitable for singing practice.

### SUMMARY

An audio processing apparatus that is connected between an audio source and an audio output is provided in accordance with a preferred embodiment. The audio processing apparatus is suitable for sing practice and includes a pitch change unit for changing the pitch of audio signals from the audio source and outputting the audio signals to the audio output.

The audio processing apparatus further includes a vocal removing unit connected between the audio source and the pitch change unit. The vocal removing unit is provided for removing vocal signals from the audio signals.

Other advantages and novel features will be drawn from the following detailed description with reference to the attached drawings.

### BRIEF DESCRIPTION OF THE DRAWINGS

FIG. 1 is a block diagram of an audio processing apparatus in accordance with a preferred embodiment of the present invention;

FIG. 2 shows a first embodiment of details of function units of the audio processing apparatus of FIG. 1; and

FIG. 3 shows a second embodiment of details of function units of the audio processing apparatus of FIG. 1.

### DETAILED DESCRIPTION OF THE EMBODIMENTS

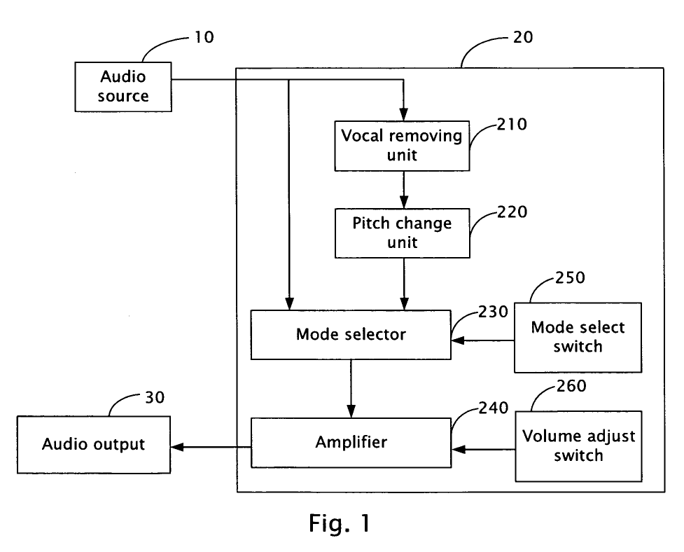

Referring to FIG. 1, the audio processing apparatus 20 in the preferred embodiment is an acoustic equipment 20 connected between an audio source 10 and audio output 30 such as a speaker. The acoustic equipment 20 is configured with a mode select switch 250. The mode select switch 250 is operable to change the acoustic equipment 20 between a normal mode and a karaoke mode. In the normal mode audio signals from the audio source 10 is amplified by an amplifier 240 in the acoustic equipment 20 and then transmitted to the audio output 30.

In the karaoke mode the audio signals is filtered to remove vocal signals by a vocal removing unit 210, changed a pitch by a pitch change unit 220, amplified by the amplifier 240 and then transmitted to the audio output 30. A mode selector 230 is employed to change the mode of the acoustic equipment 20 according to the mode select switch 250. In the preferred embodiment the mode selector 230 is a changeover switch 230 that either connects the audio source 10 to the amplifier 240 or the pitch change unit 220 to the amplifier 240.

In alternative embodiments, the changeover switch 230 connects the audio source 10 either to the vocal removing unit 210 or to the amplifier 240. The amplifier 240 is controlled by a volume adjust switch 260 configured on the acoustic equipment 20. The volume adjust switch 260 is operable to obtain a suitable output volume from the audio output 30.

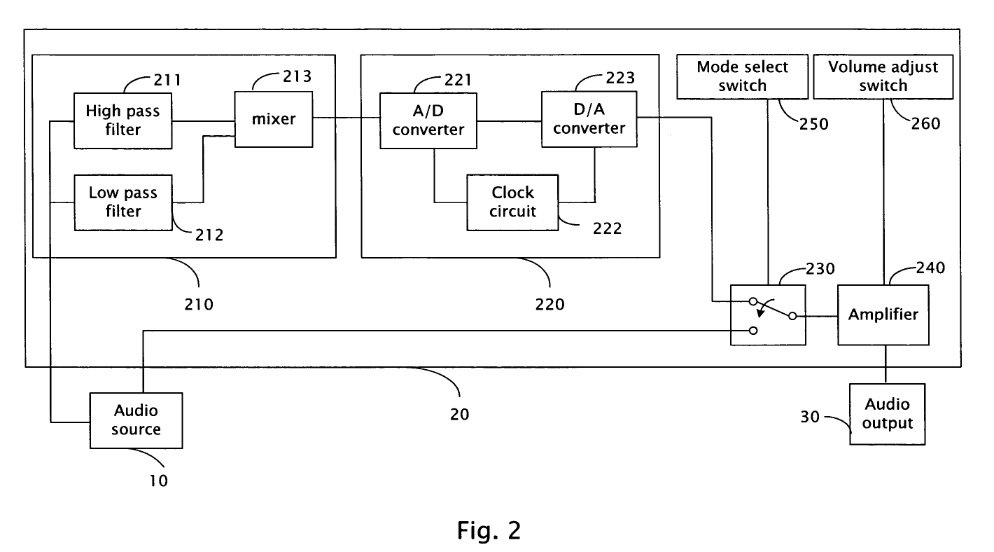

Referring to FIG. 2, the vocal removing unit 210 mainly includes a high pass filter 211, a low pass filter 212, and a mixer 213. The high pass filter 211 and the low pass filter 212 are connected in parallel between the audio source 10 and the mixer 213. The high pass filter 211 and the low pass filter 211 cooperatively filter out middle frequency components that are considered to include vocal signals from the audio signals. In depth, the high pass filter 211 passes high frequency components and the low pass filter 211 passes low frequency components from the audio signals to the mixer 213. The mixer 213 mixes the high frequency components with the low frequency components to produce mixed audio signals and output the mixed audio signals to the pitch change unit 220. Generally, the high pass filter 211 and the low pass filter 212 have suitable cutoff frequencies to efficiently remove the vocals from the audio signals. In alternative embodiments, a bandstop filter may be employed to constitute the vocal removing unit 210. The bandstop filter also has suitable cutoff frequencies to efficiently remove the vocals from the original audio signals.

The pitch change unit 220 includes an A/D (analog to digital) converter 221, and a D/A (digital to analog) converter 223 connected in series with the A/D converter 221. A clock circuit 222 is employed to provide clock signals both to the A/D converter 221 and the D/A converter 223. The A/D converter 221 has a sampling rate different from that of the D/A converter 223 in order to change the pitch of the mixed audio signals when the mixed audio signals are put through the pitch change unit 220. For example, if the D/A converter 223 has a sampling rate (hereinafter refers to as “D/A sampling rate”) higher than that of the A/D converter (hereinafter refers to as “A/D sampling rate”), the pitch of the mixed audio signals is raised by the pitch change unit 220. Otherwise, if the D/A sampling rate is lower than the A/D sampling rate, the pitch of the mixed audio signals is lowered by the pitch change unit 230. The pitch of the mixed audio signals is either lowered by a factor of N (N is a natural number ranging from 1 to 7) degrees if the D/A sampling rate is (1−N/16) times than the A/D sampling rate, or raised by a factor of N degrees if the D/A sampling rate is (1+N/8) times than the A/D sampling rate.

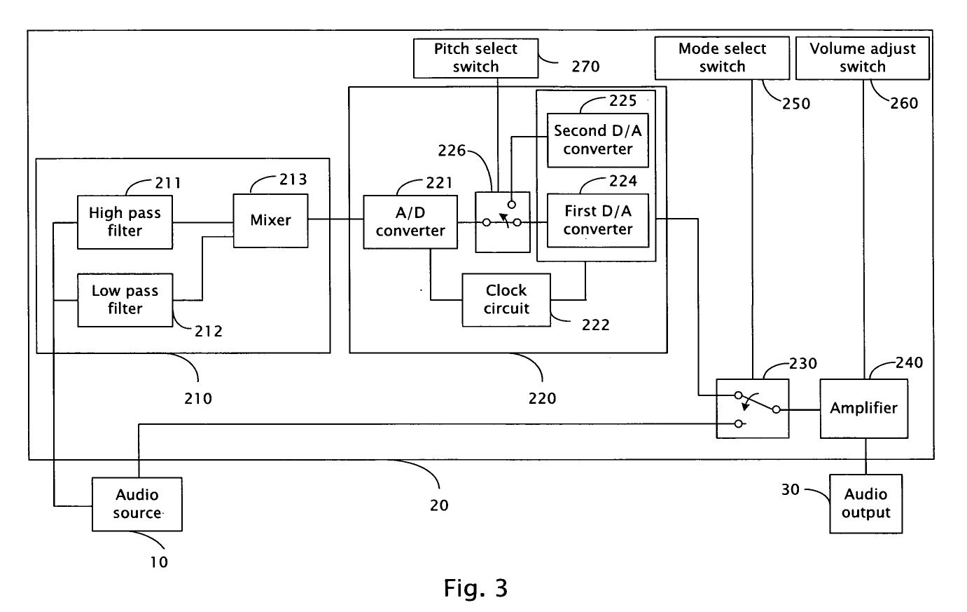

In alternative embodiments the pitch change unit 220 may include more than one D/A converters. FIG. 3 depicts an alternative embodiment of the pitch change unit 220 that includes two D/A converters. The two D/A converters refer to as a first D/A converter 224 and a second D/A converter 225 that both receive the clock signals from the clock circuit 222. The first D/A converter 224 has a sampling rate different from that of the second D/A converter 22. The first D/A converter 224 and the second D/A converter 225 are both connected to the A/D converter 221 via a pitch select circuit 226. The pitch select circuit 226 in this embodiment is also a changeover switch 226 that connects either the first D/A converter 224 or the second D/A converter 225 to the A/D converter 221 by a pitch select switch 270 configured on the acoustic equipment 20. The pitch select switch 270 is operable to select a suitable output pitch from the audio output 30.

In the embodiment relative to FIG. 3, there are two pitch selections. However in embodiments when more than two D/A converters are employed, there may be more than two pitch selections. In those embodiments, the D/A converters are connected to the A/D converter 221 via the pitch select circuit 226 which may be a multiplex switch.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. An audio processing apparatus connected between an audio source and an audio output, comprising:
a pitch change unit for changing a pitch of audio signals from the audio source and outputting the audio signals to the audio output.

2. The audio processing apparatus according to claim 1, wherein the pitch change unit comprises an analog to digital (A/D) converter and a D/A (digital to analog) converter connected in series between the audio source and the audio output, the A/D converter and the D/A converter both receive clock signals provided by a clock circuit and each have a sampling rate different from that of the other.

3. The audio processing apparatus according to claim 1, wherein the pitch change unit comprises an A/D converter and at least two D/A converters, the A/D converter and the D/A converters all receive clock signals provided by a clock circuit and each of the D/A converters has a unique sampling rate different from those of the other D/A converters.

4. The audio processing apparatus according to claim 3, wherein the pitch change unit further comprises a pitch select circuit for connecting one of the D/A converters to the A/D converter.

5. The audio processing apparatus according to claim 4, wherein the pitch select circuit is a changeover switch.

6. The audio processing apparatus according to claim 4, wherein the pitch select circuit is a multiplex switch.

7. The audio processing apparatus according to claim 4, wherein the pitch select circuit is controlled by a pitch select switch which are operable to select an output pitch of the audio signals.

8. The audio processing apparatus according to claim 1, further comprising a vocal removing unit connected between the audio source and the pitch change unit for removing vocal signals from the audio signals.

9. The audio processing apparatus according to claim 8, wherein the vocal removing unit comprises a bandstop filter.

10. The audio processing apparatus according to claim 8, wherein the vocal removing unit comprises a high pass filter, a low pass filter connected in parallel with the high pass filter and a mixer connected in serial with the high pass filter and the low pass filter.

11. The audio processing apparatus according to claim 1, further comprising an amplifier connected to the audio output.

12. The audio processing apparatus according to claim 11, further comprising a mode selector for switching the audio processing apparatus between a normal mode and a karaoke mode, in the normal mode the audio signals from the audio source being amplified and then transmitted to the audio output, and in the karaoke mode the audio signals from the audio source being changed in pitch, amplified and then transmitted to the audio output.

13. The audio processing apparatus according to claim 12, wherein the mode selector is a changeover switch.

14. The audio processing apparatus according to claim 12, wherein the mode selector is controlled by a mode select switch which is operable to select the normal mode or the karaoke mode.

15. The audio processing apparatus according to claim 1, wherein the audio processing apparatus is an acoustic equipment.
